(19) United States
(12) Patent Application Publication
(10) Pub. No.: US 2007/0180339 A1
(43) Pub. Date: Aug. 2, 2007

(54) Handling mixed-mode content in a stream of test results

(76) Inventors: Carli Connally, Fort Collins, CO (US); Reid Hayhow, La Porte, CO (US); Bryan F. Carpenter, Loveland, CO (US); Kristin Noel Casterton, Fort Collins, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/345,210

(22) Filed: Jan. 31, 2006

(51) Int. Cl. G01R 31/28

(52) U.S. Cl. 714/724

(57) ABSTRACT

In one embodiment, a system for formatting test data is provided with at least one data formatter to i) upon receiving notifications of test events, retrieve test data from a data store, and ii) generate a number of test records based on the test data. The system is also provided with an abort handler to, in response to an abort event, cause at least one of the data formatters to complete the generation of its number of test records based on currently available test data in the data store. Other embodiments are also disclosed.

### BACKGROUND

Testers, such as the Agilent Technologies 93000 System-on-chip (SOC), provide testing of complex circuitry and devices. A test is a series of instructions wherein stimuli is provided to a device under test (DUT) and test results observed. The test results may be observational (e.g., voltage at pin 10=4.8 v) or deterministic (e.g., checksum error). During the execution of a test, portions of the test results may become available to users and automated processes while the testing continues to execute. A user or automated process may suspend the test to execute ad hoc testing. The suspension of the test may be triggered by a particular value of an interim test result or by an event outside the testing environment. These ad hoc tests may be performed in order to confirm a particular test result, isolate a problem, as a matter determined by a user's discretion, or as a result of the test having to yield to a higher priority task. As the tester executes, a stream of test results is produced. The test results are then processed and/or stored for future use.

### SUMMARY OF THE INVENTION

In one embodiment, a method of processing test results is disclosed. The method comprises A) receiving a stream of test results, wherein the test results pertain to 1) a tester performing a test on at least one device under test (DUT) and 2) a testing mode initially set to a first testing mode; B) when in the first testing mode, populating a first data structure with the test results, wherein the test results are organized in the first data structure in accord with relationships between the test results; C) when in a second testing mode, populating a second data structure with the test results, wherein the test results are organized in the second data structure in accord with relationships between the test results; and D) upon determining the testing mode has been switched to the second testing mode, preserving the state of the first data structure by preserving a number of indexes referencing a number of insertion points of test results into the first data structure.

In another embodiment, a system for processing test results is disclosed. The system comprises, A) a receiver, operable to receive a stream of test results, wherein the test results pertain to 1) a tester performing a test on at least one device under test (DUT) and 2) a testing mode initially set to a first testing mode of a first and second testing mode; B) a data logger, operable to selectively populate one of a first data structure and a second data structure, with the received test results, wherein the selection of the one of the first and second data structures to populate, is in conformity with the testing mode; and C) a test mode handler, operable to, in response to a determination that the testing mode has been changed to the second testing mode, cause the state of the first data structure to be preserved by preserving a number of indexes referencing a number of insertion points of test results into the first data structure.

Other embodiments are also disclosed.

### BRIEF DESCRIPTION OF THE DRAWINGS

Illustrative embodiments of the invention are illustrated in the drawings, in which:

FIG. 1 Illustrates an exemplary method for processing test results; and

FIG. 2 illustrates an exemplary system operable to performing the method of FIG. 1.

### DETAILED DESCRIPTION

A tester executes a number of stored testing instructions (a test) to evaluate one or more devices under test (DUTs). Under ideal conditions, a test is executed from start to finish without interruption. A test may finish at different points in a test, such as at the completion of the entire test or after encountering a fatal error, but only the results of one test, from start to finish, would be produced at a time.

Operating a tester under ideal conditions is not always possible or even desirable. As a first test is performed, certain events may occur to warrant the suspension of a first test and the execution of a second test. Encountering certain errors, interruptions by higher priority testing tasks, observed trends indicating questionable test result reliability, and to exercise an operator's discretion are some of the events that make suspending a first test, for the execution of a second test, desirable. One particular example of an event that warrants the suspension of a first test, in order to perform a second test, is when the first test is the execution of a production mode test and the second test is a debug mode test. An operator may be performing a production mode test and encounter an event, such as an error, that warrants further investigation outside of the scope of the production mode test. The operator then suspends the production mode tests and performs additional, debug mode testing. The debug mode tests may execute different test steps than those of the production mode test, report verbose test details, or execute the same test steps as in the production mode tests but in a different order, number of repetitions, or with alternate input values. After the operator's investigation has concluded, the production mode test resumes.

Testers produce a single stream of test results even when the tester's operation is split into two or more modes. Suspending the production of test results when switching from the first testing mode to a second testing mode would prevent the first testing mode test results from being tainted by the second testing mode test results, however, it would also preclude the evaluation of the second testing mode test results.

Manually stopping the processing of test results upon switching testing modes will cause the relationship between the test results to be lost. Resuming the first test, after executing the second test, would in reality be the execution of a third test as the test results are no longer associated with the initial first set of test results. Additionally, processing test results may be performed on secondary resources not operating in lockstep with the generation of test results. As a result, switching the tester from the first to second testing mode, or vice versa, may be difficult to synchronize with the mode of the processors analyzing the test results. Alternatively, the stream of test results may be processed without consideration of the testing mode and produce heterogeneous testing mode results, which may lead to a skewed or flawed evaluation of the DUT. The following embodiments solve these and other problems and advance the art of tester operations.

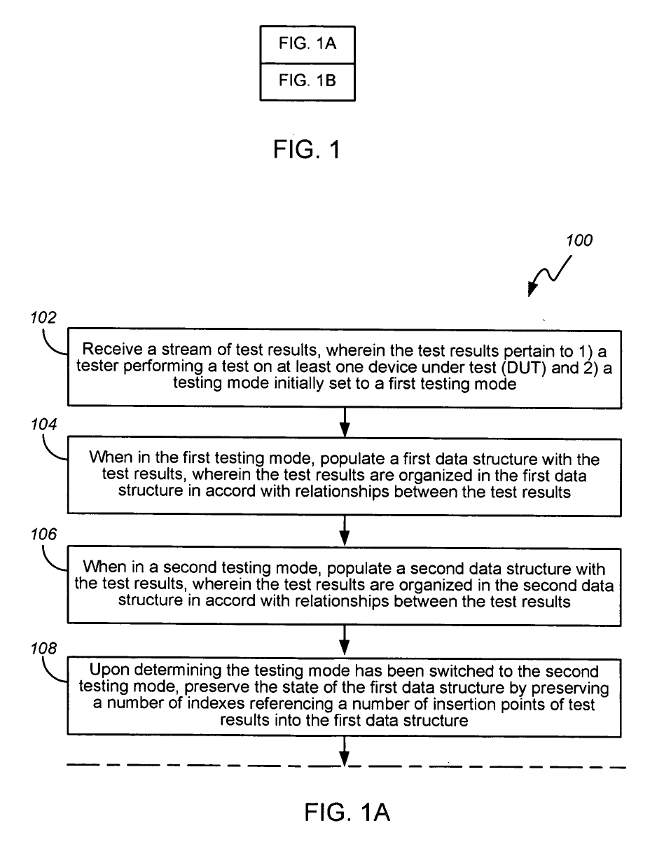

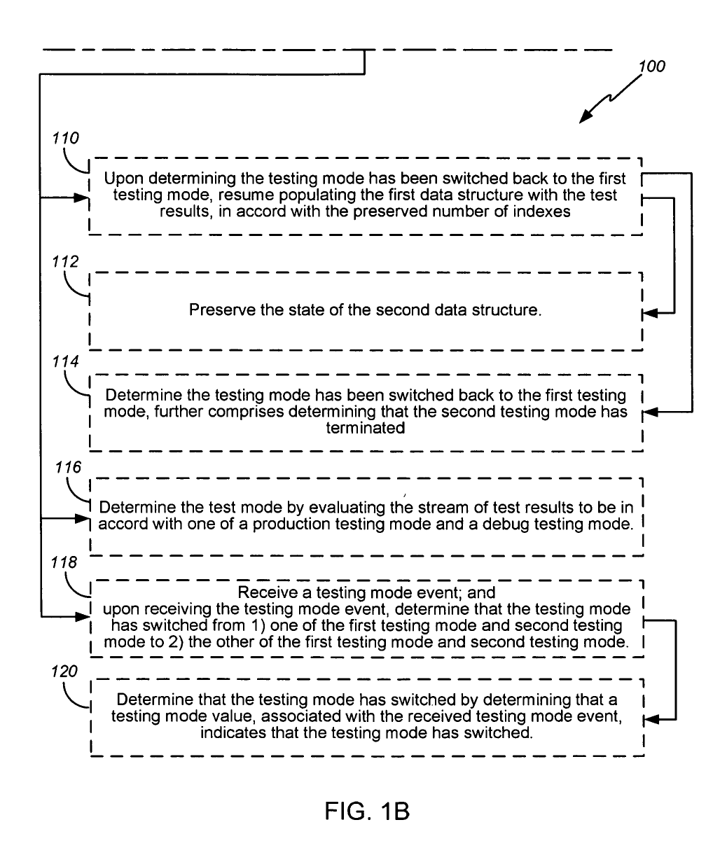

FIG. 1 illustrates exemplary method 100 for processing test results. Method 100 contains steps 102, 104, 106, 108 for A) receiving a stream of test results, wherein the test results pertain to 1) a tester performing a test on at least one device under test (DUT) and 2) a testing mode initially set to a first testing mode; B) when in the first testing mode, populating a first data structure with the test results, wherein the test results are organized in the first data structure in accord with relationships between the test results; C) when in a second testing mode, populating a second data structure with the test results, wherein the test results are organized in the second data structure in accord with relationships between the test results; and D) upon determining the testing mode has been switched to the second testing mode, preserving the state of the first data structure by preserving a number of indexes referencing a number of insertion points of test results into the first data structure.

In one embodiment, the testing mode is one of two modes. In other embodiments more than two testing modes are provided, wherein the tester is initially set in a first of many testing modes.

Receiving 102 the stream of test results necessitates receiving the output of the tester. In one embodiment, the stream is received 102 directly from the tester whereas in another embodiment the stream is received 102 by reading a repository (e.g., buffer, file) that receives the output of the tester.

The characteristics defining a mode are a matter of design choice wherein two or more tests produce test results to be evaluated separately. Any test operation, wherein the tester is executing one test and the one test is suspended to execute a second test, wherein the two tests produce test results to be generated for independent evaluation, warrants multiple test modes. The more common designation between first and second testing modes are the production/debug testing modes. Swapping DUTs may also warrant switching from first to a second testing mode. Another example of a first and second testing mode occurs when executing a portion a first testing mode test repeatedly, wherein the increased number of executions would taint the results of the first test.

Populating 104 the first data structure, when in the first testing mode and populating 106 a second data structure, when in a second testing mode, results in the first and second data structures each containing test results that are associated with each respective testing mode. In other embodiments, more than two data structures are populated with test results associated with each respective testing mode. The data in the first and second data structures may then be processed and/or saved.

Preserving 108 the state of the first data structure by preserving a number of indexes referencing a number of insertion points of test results into the first data structure, provides a means to locate insertion points of test results. An index, such as a pointer, array index, record number or other position indicia locates the point of insertion of test results and facilitates locating a next insertion point for a yet to be received test result. In one embodiment, the first or second data structure is linearly organized (e.g., flat-file) wherein all test records are sequentially wrote as they are received. In such an embodiment, a single index may be used. In other embodiments, more complex data structures (e.g., database, multiple attribute “struct” structure, software objects, array, plurality of single attribute elements) receive data and are indexed for multiple locations in the data structure. In a hypothetical example, a first data structure may maintain separate sets of indexes for test records separately associating test results indicating test results that are 1) voltage test result and 2) amperage test result.

Method 100, upon execution of steps 102-108, optionally executes steps 110, 116, and 118. Upon execution of step 110, optional step 112 and/or optional step 114 are executed. Upon execution of step 118, optional step 120 is executed.

Method 100 contains step 110 for, upon determining the testing mode has been switched back to the first testing mode, resuming the populating the first data structure with the test results, in accord with the preserved number of indexes. The sub-step of determining that the test mode has switched may invoke a component (e.g., test mode monitor 256) or process (e.g., step 114, 116, and 118-120) to aid in the determination of the mode switching back to the first testing mode. In one embodiment, switching is the toggling between two modes and in other embodiments, switching is the selection of one of a number of modes to be a current testing mode.

Method 100 contains step 112 for, preserving the state of the second data structure. Preserving 112 further comprises preserving the second data structure by preserving a number of indexes referencing a number of insertion points of test results into the second data structure.

Method 100 contains step 114 for, determining the testing mode has been switched back to the first testing mode by determining that the second testing mode has terminated.

Method 100 contains step 116 for, determining the test mode by evaluating the stream of test results to be in accord with one of a production testing mode and a debug testing mode.

Method 100 contains step 118 for, receiving a testing mode event and upon receiving the testing mode event, determining that the testing mode has switched from 1) one of the first testing mode and second testing mode to 2) the other of the first testing mode and second testing mode. In one embodiment, the test mode event is a token inserted into the stream of test results. In another embodiment, the test mode event is change to the contents of a memory location holding a flag, semaphore, counter, or other indicia of the test mode.

Method 100 contains step 120 for, determining that the testing mode has switched by determining that a testing mode value, associated with the received testing mode event, indicates that the testing mode has switched. In one embodiment, a plurality of test mode events are received, such as when a plurality of test devices are each associated with the tester each device switched from a first, production mode, to a second, debug mode, and each device causes a test mode event to be generated indicating the second, debug mode, is now the current mode. Evaluating a testing mode value determines the testing mode, such that a received plurality of testing mode events, each indicating “debug mode” are processed properly (e.g., ignored) once the testing mode has already responding to the first testing event indicating “debug mode.” In a further embodiment, the testing mode value indicates which, of a number of testing modes, is the current testing mode.

In another embodiment, a number of machine-readable media having stored thereon sequences of instructions that, when executed by a machine, cause the machine to perform the actions of method 100.

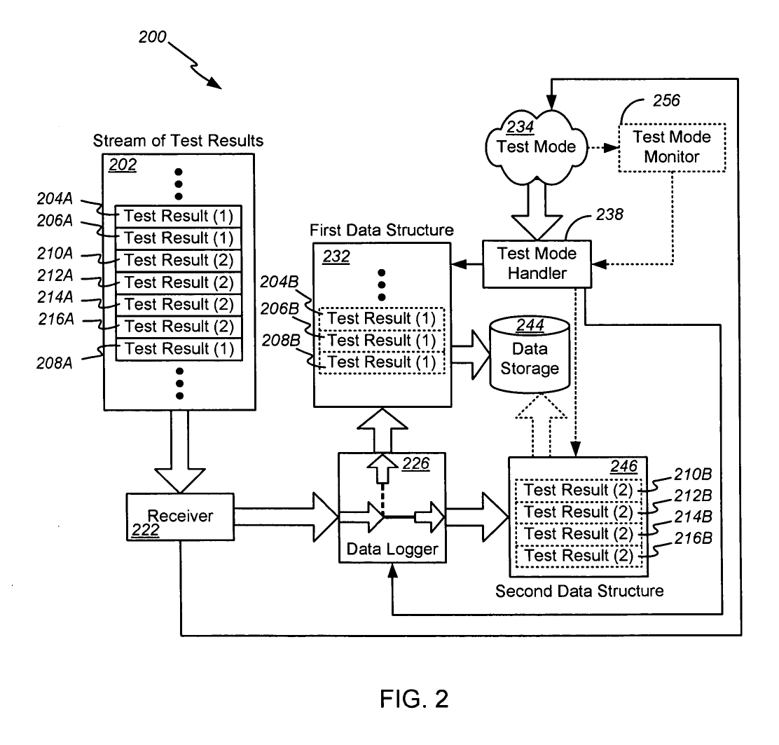

FIG. 2 illustrates exemplary system 200 operable to performing the method of FIG. 1. In one embodiment, stream of test results 202 is the direct output of a tester executing a test on at least one DUT. In another embodiment, stream of test results 202 is received from a tester via a buffer (e.g., file, memory location, storage device). Stream of test results 202 contains test results 204-216. To illustrate the switching of test mode 234 from a first testing mode, to a second testing mode, and then back to the first testing mode, the embodiment of FIG. 2 illustrates stream of test results 202 being received in the order of: first mode test results (1) 204A, 206A, second mode test results (2) 210A, 212A, 214A, 216A, and then back to first mode test results (1) 208A. As such, the embodiment illustrates operating a tester in first testing mode, switching to a second testing mode, then switching back to the first testing mode.

As a result of implementing system 200, test results 204-216 are moved from stream of test results 202 to either first data structure 232 or second data structure 246, so that first mode test results (1) 204A, 206A, 208A are moved to first data structure 232, as first mode test results (1) 204B, 206B, 208B and second mode test results (2) 210A, 212A, 214A, 216A are moved to second data structure 232, as second mode test results (2) 210B, 212B, 214B, 216B. The relationship between ones of test results 204-216, associated with the same testing mode, are then preserved in first data structure 232 and second data structure 246. For example, the order in which ones of test results 204-216 are received by receiver 222, are preserved in first data structure 232, for first mode test results (1) 204, 206, 208, and second data structure 246, for second test mode test results (2) 210, 212, 214, 216.

Receiver 222 receives test results 204-216. In one embodiment, receiver 222 receives test results 204-216 by reading stream of test results 202 (e.g., “pull”). In another embodiment, receiver 222 receives test results 204-216 by receiving (e.g., “push”) test results 206-216, for example receiver 222 may be called with parameters (e.g., reference pointers, values) associated with ones of test results 204-216.

Receiver 222 forwards test results 204-216 to data logger 226. Data logger 226 is operable to selectively route test results 204-216 to either first data structure 232 or second data structure 246 in accord with test mode 234. In further embodiments, data logger 226 is operable to selectively route test results 204-216 to a number of data structures in addition to first data structure 232 and second data structure 246. Test mode 234, in the embodiment illustrated, is either a first testing mode or a second testing mode and is set, such as by receiver 222.

While initially in the first testing mode, data logger 226 initially routes test results 204, 206 to first data structure 232. After reading test result 206, test mode 234 switches to the second testing mode. Upon determining test mode 234 has changed 1) data logger 226 begins to populate second data structure 246 with test results 210, 212, 214, 216 and 2) test mode handler 238 causes the state of first data structure 232 to be preserved in data storage 244.

In one embodiment, testing mode 234 is determined by receiver 222. In a first further embodiment, receiver 222 reads a token (not shown) that is a discrete record in stream of test results 202, such as would be inserted between test result 206 and test result 210, to indicate a switch from the first to second testing mode, and again between test result 216 and 208 to indicate a switch back to the first testing mode. In a second further embodiment, the testing mode is encoded in ones of test results 204-216.

In another embodiment, the value of test mode 234 is read from a source other than stream of test results 202. For example, a semaphore, toggle, or other memory value is set by the tester. In another example, the value of test mode 234 is set in accessible memory by at least one of the tester, receiver 222, and test mode monitor 256. In embodiments wherein test mode 234 is polled, test mode monitor 256 determines when the testing mode has changed and notifies test mode handler 238. Test mode handler in turn notifies data logger 226 of the value of test mode 234.

If after receiving test result 216, test mode 234 switches back to the first testing mode, 1) data logger 226 resumes populating first data structure 232 with test result 208 and 2) test mode handler 238 causes the state of second data structure 246 to be preserved in data storage 244.

What is claimed is:

1. A method of processing test results, comprising:
receiving a stream of test results, wherein the test results pertain to 1) a tester performing a test on at least one device under test (DUT) and 2) a testing mode initially set to a first testing mode;
when in the first testing mode, populating a first data structure with the test results, wherein the test results are organized in the first data structure in accord with relationships between the test results;
when in a second testing mode, populating a second data structure with the test results, wherein the test results are organized in the second data structure in accord with relationships between the test results; and
upon determining the testing mode has been switched to the second testing mode, preserving the state of the first data structure by preserving a number of indexes referencing a number of insertion points of test results into the first data structure.

2. The method of claim 1, further comprising, upon determining the testing mode has been switched back to the first testing mode, resume populating the first data structure with the test results, in accord with the preserved number of indexes.

3. The method of claim 2, further comprising, preserving the state of the second data structure.

4. The method of claim 2, wherein determining the testing mode has been switched back to the first testing mode, further comprises determining that the second testing mode has terminated.

5. The method of claim 1, further comprising, determining the test mode by evaluating the stream of test results to be in accord with one of a production testing mode and a debug testing mode.

6. The method of claim 1, further comprising:
receiving a testing mode event; and
upon receiving the testing mode event, determining that the testing mode has switched from 1) one of the first testing mode and second testing mode to 2) the other of the first testing mode and second testing mode.

7. The method of claim 6, further comprising determining that the testing mode has switched by determining that a testing mode value, associated with the received testing mode event, indicates that the testing mode has switched.

8. A system for processing test results, comprising:
a receiver, operable to receive a stream of test results, wherein the test results pertain to 1) a tester performing a test on at least one device under test (DUT) and 2) a testing mode initially set to a first testing mode of a first and second testing mode;
a data logger, operable to selectively populate one of a first data structure and a second data structure, with the received test results, wherein the selection of the one of the first and second data structures to populate, is in conformity with the testing mode; and
a test mode handler, operable to, in response to a determination that the testing mode has been changed to the second testing mode, cause the state of the first data structure to be preserved by preserving a number of indexes referencing a number of insertion points of test results into the first data structure.

9. The system of claim 8, further comprising a test mode monitor, operable to monitor the system and determine that the testing mode has been changed.

10. The system of claim 9, wherein, the mode handler is further operable to, in response to a determination that the testing mode has been switched back to the first testing mode, cause the state of the second data structure to be preserved.

11. The system of claim 9, wherein the test mode handler is further operable to, preserve the state of the second data structure by preserving a number of indexes referencing a number of insertion points of test results into the second data structure.

12. The system of claim 8, wherein the test mode monitor determines that the testing mode has been switched back to the first testing mode upon determining that the second testing mode has terminated.

13. The system of claim 8, wherein:
the receiver, is further operable to receive a testing mode event; and
the test mode monitor, is further operable to determine that the testing mode has been switched from 1) one of the first testing mode and second testing mode to 2) the other of the first testing mode and second testing mode, upon receipt of the testing mode event.

14. A number of machine-readable media having stored thereon sequences of instructions that, when executed by a machine, cause the machine to perform the actions of:
receiving a stream of test results, wherein the test results pertain to 1) a tester performing a test on at least one device under test (DUT) and 2) a testing mode initially set to a first testing mode;
when in the first testing mode, populating a first data structure with the test results, wherein the test results are organized in the first data structure in accord with relationships between the test results;
when in a second testing mode, populating a second data structure with the test results, wherein the test results are organized in the second data structure in accord with relationships between the test results; and
upon determining the testing mode has been switched to the second testing mode, preserving the state of the first data structure by preserving a number of indexes referencing a number of insertion points of test results into the first data structure.

15. The media of claim 14, further comprising instructions for, upon determining the testing mode has been switched back to the first testing mode, resume populating the first data structure with the test results, in accord with the preserved number of indexes.

16. The media of claim 15, further comprising instructions for, preserving the state of the second data structure.

17. The media of claim 16, wherein the instructions for determining the testing mode has been switched back to the first testing mode, further comprises instructions for determining that the second testing mode has terminated.

18. The media of claim 16, wherein the instructions for determining the test mode further comprise instructions for evaluating the stream of test results to be in accord with one of a production testing mode and a debug testing mode.

19. The instructions of claim 14, further comprising instructions for:
receiving a testing mode event; and
upon receiving the testing mode event, determining that the testing mode has switched from 1) one of the first testing mode and second testing mode to 2) the other of the first testing mode and second testing mode.

20. The instructions of claim 19, wherein the instructions for determining that the testing mode has switched further comprise instructions for determining that a testing mode value, associated with the received testing mode event, indicates that the testing mode has switched.
